(19) United States
(12) Patent Application Publication
(10) Pub. No.: US 2022/0128623 A1
(43) Pub. Date: Apr. 28, 2022

(54) DEVICE FOR OVER-THE-AIR TESTING

(71) Applicant: Powertech Technology Inc., Hsinchu (TW)

(72) Inventors: Fu-Hsiang CHANG, Hsinchu (TW); Ming-Hsiu HSIEH, Hsinchu (TW); Yuan-Jung LU, Hsinchu (TW); Shin-Kung CHEN, Hsinchu (TW)

(73) Assignee: Powertech Technology Inc., Hsinchu (TW)

(21) Appl. No.: 17/224,196

(22) Filed: Apr. 7, 2021

(30) Foreign Application Priority Data
Oct. 22, 2020 (TW) 109136708

(51) Int. Cl. G01R 31/28

(52) U.S. Cl. CPC G01R 31/2867

(57) ABSTRACT

A device for Over-the-Air testing includes a carrier unit, an automatic positioning member and a housing unit. The automatic positioning member is adapted to convey an object under test to an electrical connection zone of the carrier. The housing unit includes a housing shell, a pressing plate and a receiver. The housing shell defines a testing space that has an open end where the pressing plate is disposed. The housing unit and the carrier unit are movable relative to each other. When the carrier unit abuts the housing unit, the object under test is exposed to the testing space and is pressed against the electrical connection zone by the pressing plate so that electromagnetic waves from the object under test are received by the receiver.

### CROSS-REFERENCE TO RELATED APPLICATION

This application claims priority to Taiwanese Invention Patent Application No. 109136708, filed on Oct. 22, 2020.

### FIELD

The disclosure relates to a device for Over-the-Air testing, and more particularly to a device for Over-the-Air testing of an object that can emit electromagnetic waves.

### BACKGROUND

In recent years, the fifth generation of mobile network technology (hereinafter also referred to as “the 5G technology”) has been developed worldwide. The 5G technology provides greater bandwidth and higher download speeds than previous mobile network technology. Most of packaged integrated circuits featuring the 5G technology are designed with antenna-in-package technique, which integrates an integrated circuit and an antenna in an integrated circuit package. Therefore, in order to evaluate the performance and reliability of integrated circuit packages that contain an antenna, Over-the-Air testing is required.

However, a conventional device for Over-the-Air testing can test only one specific type of integrated circuit package that corresponds in shape to a jig of the conventional device. In addition, even if the type of integrated circuit package can match with the jig of the conventional device, the integrated circuit package has to be positioned on the jig by a manual operation before testing, thus rendering the testing more complicated.

### SUMMARY

Therefore, an object of the disclosure is to provide a device for Over-the-Air testing that can alleviate at least one of the drawbacks of the prior art.

According to the disclosure, the device for Over-the-Air testing includes a carrier unit, an automatic positioning member and a housing unit. The carrier unit includes a holding base that has an electrical connection zone. The automatic positioning member is adapted to convey an object under test to the electrical connection zone. The housing unit includes a housing shell, a pressing plate and a receiver. The housing shell has a testing space and an open end. The pressing plate is disposed at the open end. The receiver is disposed on the housing shell inside the testing space. The open end of the housing shell of the housing unit is spaced apart from the carrier unit and faces the carrier unit. The housing unit and the carrier unit are movable relative to each other. When the pressing plate of the housing unit and the holding base of the carrier unit abut against each other to close the open end, the object under test is exposed to the testing space and is pressed against the electrical connection zone by the pressing plate so that electromagnetic waves emitted by the object under test are receivable by the receiver of the housing unit.

### BRIEF DESCRIPTION OF THE DRAWINGS

Other features and advantages of the disclosure will become apparent in the following detailed description of the embodiment with reference to the accompanying drawings, of which:

FIG. 1 is a partly, sectional schematic view of an embodiment of a device for Over-the-Air testing according to the disclosure; and

FIG. 2 is a partly, sectional schematic view illustrating an object under test being exposed to a testing space of the embodiment.

### DETAILED DESCRIPTION

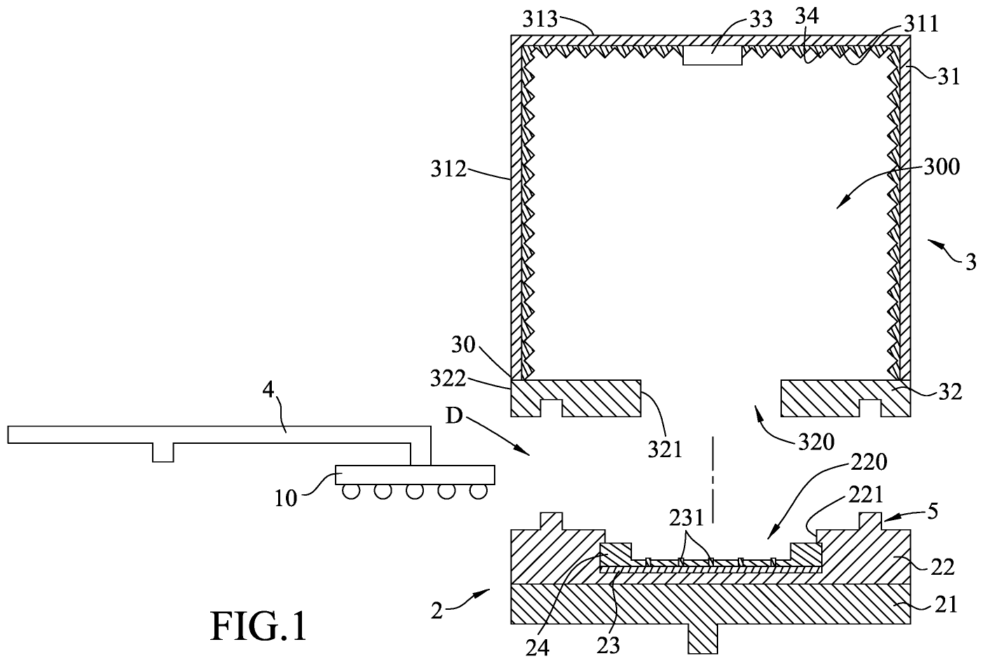

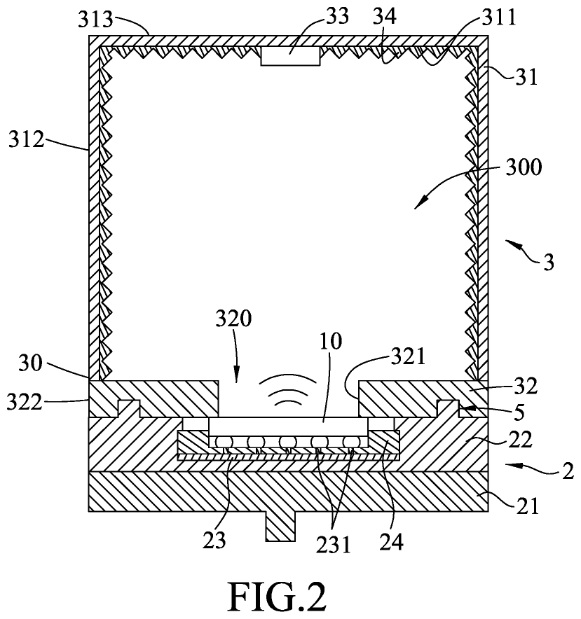

Referring to FIGS. 1 and 2, an embodiment of a device for Over-the-Air testing according to the disclosure is adapted to test an object 10 under test. The object 10 under test has an antenna that emits electromagnetic waves. Preferably, the object 10 under test may be a packaged integrated circuit that emits millimeter-length electromagnetic waves. In this embodiment, the object 10 under test is a packaged integrated circuit that features the 5G technology and that is designed with the antenna-in-package technique, but is not limited thereto.

The device of the disclosure includes a carrier unit 2, an automatic positioning member 4 and a housing unit 3. The carrier unit 2 includes a lifting platform 21, a holding base 22, a circuit member 23 and a connecting jig 24. The holding base 22 is disposed on the lifting platform 21, and has an electrical connection zone 220, and a concave part 221 formed at a surface thereof that faces the housing unit 3 so as to serve as the electrical connection zone 220. The circuit member 23 and the connecting jig 24 are disposed in the concave part 221 of the holding base 22 in a manner that the circuit member 23 is disposed on the electrical connection zone 220 of the holding base 22 and the connecting jig 24 is disposed over the circuit member 23 for holding the object 10 under test on top of the circuit member 23. The circuit member 23 has a plurality of probes 231 that protrude through the connecting jig 24. The object 10 under test is electronically connected to the probes 231 of the circuit member 23 when the object 10 under test is positioned at the electrical connection zone 220 of the holding base 22, that is to say, when the object 10 under test is held by the connecting jig 24 on top of the circuit member 23.

The automatic positioning member 4 is adapted to convey the object 10 under test to the electrical connection zone 220 of the holding base 22 of the carrier unit 2 such that the object 10 under test is held by the connecting jig 24 on top of the circuit 23. It is noted that in this embodiment, the automatic positioning member 4 is a mechanical arm, but is not limited thereto. In one or more other embodiments, the automatic positioning member 4 maybe one automatically operable to convey and place the object 10 under test at the electrical connection zone 220.

The housing unit 3 includes a housing shell 31, a pressing plate 32, a receiver 33 and an electromagnetic wave absorber 34. The housing shell 31 has a testing space 300, an open end 30, and an inner surface 311 inside the testing space 300. The pressing plate 32 is disposed at the open end 30, spans the open end 30, and has a through hole 320, an inner periphery 321 surrounding the through hole 320, and an outer periphery 322 surrounding the inner periphery 321, and that is removably attached to the open end 30. In particular, the housing shell 31 has a surrounding wall 312 extending around the testing space 300, and an end wall 313 connecting one end of the surrounding wall 312 and bounding one side of the testing space 300. The open end 30 is situated at another end of the surrounding wall 312 opposite to the end wall 313.

The receiver 33 is disposed on the inner surface 311 of the housing shell 31 inside the testing space 300. The electromagnetic wave absorber 34 is disposed on the inner surface 311. Preferably, the electromagnetic wave absorber 34 is disposed on the inner surface 311 in a manner that the inner surface 311 is almost entirely covered by the electromagnetic wave absorber 34. The material of the electromagnetic wave absorber 34 may be selected from any suitable materials depending on the range of the electromagnetic spectrum emitted by the object 10 under test. The holding base 22 of the carrier unit 2 and the pressing plate 32 are made of non-metal materials.

The open end 30 of the housing shell 31 of the housing unit 3 is spaced apart from the carrier unit 2 and faces the carrier unit 2. The housing unit 3 and the carrier unit 2 are movable relative to each other. In this embodiment, the lifting platform 21 of the carrier unit 2 is operable to carry the holding base 22 of the carrier unit 2 to move toward the housing unit 3. When the pressing plate 32 of the housing unit 3 and the holding base 22 abut against each other to close the open end 30, the object 10 under test is exposed to the testing space 300 and is pressed against the electrical connection zone 220 of the holding base 22 by the pressing plate 32. Therefore, electromagnetic waves emitted by the object 10 under test are receivable by the receiver 33 of the housing unit 3.

It is noted that, when the pressing plate 32 and the holding base 22 abut against each other, the housing unit 3 and the carrier unit 2 are interengageable through a recess-and-protrusion engagement mechanism 5. Further, the electrical connection zone 220 of the holding base 22 is registered with the through hole 320 of the pressing plate 32 when the holding base 22 abuts against the pressing plate 32 so that the object 10 is exposed to the testing space 300 through the through hole 320 of the pressing plate 32. Note that the size of the through hole 320 of the pressing plate 32 of the housing unit 3 is smaller than that of the electrical connection zone 220; thus the pressing plate 32 can press the object 10 when the holding base 22 abuts the pressing plate 32.

In this embodiment, before Over-the-Air testing, the open end 30 of the housing unit 3 is spaced apart from the holding base 22 of the carrier unit 2, faces downwardly and faces toward the holding base 22 of the carrier unit 2. The housing unit 3 is spaced apart from the carrier unit 2 by a distance (D) (see FIG. 1). Next, the automatic positioning member 4 is operated to convey the object 10 under test and then deliver the same at the electrical connection zone 220 of the holding base 22, specifically, on the connecting jig 24 disposed on top of the circuit member 23. The object 10 is thus positioned on the holding base 22 through the connecting jig 24, and is electronically connected to the probes 231 of the circuit member 23. After the object 10 is positioned, the lifting platform 21 of the carrier unit 2 is operated to carry the holding base 22 to move toward the housing unit 3 to close the open end 30. Therefore, the object 10 is exposed to the testing space 300 and is pressed by the pressing plate 32. Specifically, because the size of the through hole 320 of the pressing plate is smaller than the size of the electrical connection zone 220, the inner periphery 321 of the pressing plate 32 (see FIG. 2) extends over part of the electrical connection zone 220 or the connecting jig 24 and presses part of the object 10 against the connecting jig 24 when the pressing plate 32 and the holding base 22 abut against each other. This provides a tight connection between the object 10 and the probes 231. Then, the object 10 is tested when the electromagnetic waves emitted by the object 10 are received by the receiver 33 of the housing unit 3.

It is worth mentioning that the holding base 22 is removably attached to the lifting platform 21 and the pressing plate 32 is removably attached to the open end 30 of the housing shell 31. Therefore, each of the holding base 22 and the pressing plate 32 are replaceable. That is to say, the holding base 22 or the pressing plate 32 maybe replaced by a new one that suits the type of the object 10 to be tested. For removable attachment of the holding base 22 or the pressing plate 32, suitable connecting means may be, but not limited to, screw fasteners, an interlocking mechanism, or an adhesive connection. When the holding base 22 is replaced by a new one, the pressing plate 32 may be replaced by a new one that is able to cooperate with the new holding base 22 to accommodate the object 10 to be tested. For replacement, multiple holding bases 22 with various configurations and multiple pressing plates 32 with various configurations may be provided for being interchangeably used.

In summary, by virtue of the automatic positioning member 4 being operable to convey the object 10 to the electrical connection zone 220 of the holding base 22, a direct manual operation may be dispensed with during the whole process of Over-the-Air testing. By virtue of the holding base 22 of the carrier unit 2 and the pressing plate 32 of the housing unit 3 that are detachable for replacement, various types of objects 10 may be tested by using the device of the disclosure.

In the description above, for the purposes of explanation, numerous specific details have been set forth in order to provide a thorough understanding of the embodiment. It will be apparent, however, to one skilled in the art, that one or more other embodiments maybe practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A device for Over-the-Air testing comprising:
a carrier unit including a holding base that has an electrical connection zone;
an automatic positioning member operable to convey an object under test to said electrical connection zone; and
a housing unit including a housing shell, a pressing plate and a receiver, said housing shell having a testing space and an open end, said pressing plate being disposed at said open end, said receiver being disposed on said housing shell inside said testing space;
wherein said open end of said housing shell of said housing unit is spaced apart from said carrier unit and faces said carrier unit, said housing unit and said carrier unit being movable relative to each other;
wherein, when said pressing plate of said housing unit and said holding base of said carrier unit abut against each other to close said open end, the object under test is exposed to said testing space and is pressed against said electrical connection zone by said pressing plate, whereby electromagnetic waves emitted by the object under test are receivable by said receiver of said housing unit.

2. The device for Over-the-Air testing as claimed in claim 1, wherein said carrier unit further includes a lifting platform, said holding base of said carrier unit being disposed on said lifting platform, said lifting platform being operable to carry said holding base to move toward said housing unit so that said holding base abuts against said pressing plate of said housing unit.

3. The device for Over-the-Air testing as claimed in claim 2, wherein said housing shell has a surrounding wall extending around said testing space, and an end wall connecting one end of said surrounding wall and bounding one side of said testing space, said open end of said housing shell being situated at another end of said surrounding wall opposite to said end wall, said pressing plate being removably attached to said open end of said surrounding wall, said holding base being removably attached to said lifting platform.

4. The device for Over-the-Air testing as claimed in claim 3, wherein said pressing plate spans said open end of said housing shell, and has a through hole, an inner periphery surrounding said through hole, and an outer periphery surrounding said inner periphery, said outer periphery being removably attached to said open end of said housing shell, said electrical connection zone of said holding base being registered with said through hole when said holding base abuts against said pressing plate so that the object under test is exposed to said testing space through said through hole.

5. The device for Over-the-Air testing as claimed in claim 1, wherein said housing unit further includes an electromagnetic wave absorber, said housing shell of said housing unit having an inner surface inside said testing space of said housing shell, said electromagnetic wave absorber being disposed on said inner surface.

6. The device for Over-the-Air testing as claimed in claim 1, wherein said housing shell (31) of said housing unit has an inner surface inside said testing space of said housing shell, said receiver of said housing unit being disposed on said inner surface.

7. The device for Over-the-Air testing as claimed in claim 1, wherein said carrier unit further includes a circuit member disposed on said electrical connection zone of said holding base of said supporting unit, the object under test being electronically connected to said circuit member when the object under test is positioned at said electrical connection zone.

8. The device for Over-the-Air testing as claimed in claim 7, wherein said carrier unit further includes a connecting jig disposed over said circuit member of said carrier unit for holding the object under test on top of said circuit member.

9. The device for Over-the-Air testing as claimed in claim 8, wherein said holding base of said carrier unit has a concave part formed in a surface thereof that faces said housing unit so as to serve as said electrical connection zone of said holding base, said circuit member and said connecting jig of said carrier unit being disposed in said concave part, said circuit member having a plurality of probes that protrude through said connecting jig, the object under test being electronically connected to said probes when the object under test is held by said connecting jig on top of said circuit member.

10. The device for Over-the-Air testing as claimed in claim 1, wherein said holding base of said carrier unit and said pressing plate of said housing unit are made of non-metal materials.

11. The device for Over-the-Air testing as claimed in claim 1, wherein said automatic positioning member is a mechanical arm.
